(19) United States
(12) Patent Application Publication
(10) Pub. No.: US 2017/0033572 A1
(43) Pub. Date: Feb. 2, 2017

(54) CAPACITY ESTIMATION IN A SECONDARY BATTERY

(71) Applicant: Robert Bosch GmbH, Stuttgart (DE)

(72) Inventors: Jens Becker, Ludwigshafen Am Rhein (DE); Michael Erden, Bebra (DE); Olivier Cois, Kernen (DE); Triantafyllos Zafiridis, Heilbronn (DE)

(21) Appl. No.: 15/219,864

(22) Filed: Jul. 26, 2016

Related U.S. Application Data
(63) Continuation-in-part of application No. 15/214,627, filed on Jul. 20, 2016.

(30) Foreign Application Priority Data
Jul. 27, 2015 (DE) 10 2015 214 128.4

(51) Int. Cl. H02J 7/00; G01R 31/36

(52) U.S. Cl. CPC H02J 7/0021; G01R 31/3624; G01R 31/3651; H02J 7/0024

(57) ABSTRACT

Methods and systems for managing a battery system. The battery system includes at least on battery cell and sensors configured to measure a voltage and a current of the battery cell. The method includes receiving measured voltage and current, calculating the capacity of the battery cell and regulating the charging or discharging of the battery cell based on the capacity of the battery cell.

### CROSS REFERENCES TO RELATED APPLICATIONS

This application is a continuation-in-part of prior application Ser. No. 15/214,627, filed on Jul. 20, 2016, the contents of which are hereby incorporated by reference in their entirety.

### FIELD

The disclosure generally relates to secondary batteries, and more particularly to a method of determining the capacity of a secondary battery.

### BACKGROUND OF THE INVENTION

Rechargeable lithium batteries are attractive energy storage devices for portable electric and electronic devices and electric and hybrid-electric vehicles because of their high specific energy compared to other electrochemical energy storage devices. A typical lithium cell contains a negative electrode, a positive electrode, and a separator located between the negative and positive electrodes. Both electrodes contain active materials that react with lithium reversibly. In some cases, the negative electrode may include lithium metal, which can be electrochemically dissolved and deposited reversibly. The separator contains an electrolyte with a lithium cation, and serves as a physical barrier between the electrodes such that none of the electrodes are electrically connected within the cell.

Typically, during charging, there is generation of electrons at the positive electrode and consumption of an equal amount of electrons at the negative electrode. During discharging, opposite reactions occur.

During repeated charge/discharge cycles of the battery undesirable side reactions occur. These undesirable side reactions result in the reduction of the capacity of the battery to provide and store power.

### SUMMARY OF THE INVENTION

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

Embodiments of the disclosure are related to a battery system including, one or more battery cells having an anode, a cathode and an electrically insulating separator located between the anode and the cathode, wherein the electrically insulating separator electrically insulates the anode from the cathode; and a battery management system comprising a processor and a memory storing instructions. The instructions, when executed by the processor, cause the battery management system to receive a functionalized representation of one or more characteristics of one or more battery cells at a first time. The instructions, when executed by the processor, also cause the battery management system to receive one or more measured characteristics of one or more battery cells from one or more sensors at a second time, including a characteristic selected from the group consisting of a current measurement of the one or more battery cells, a voltage measurement of the one or more battery cells and a charge measurement of the one or more battery cells. The instructions, when executed by the processor, also cause the battery management system to receive one or more measured characteristics of the one or more battery cells from the one or more sensors at a third time, including a characteristic selected from the group consisting of a current measurement of the one or more battery cells, a voltage measurement of the one or more battery cells and a charge measurement of the one or more battery cells, wherein the third time is after the second time. The instructions, when executed by the processor, also cause the battery management system to estimate one or more characteristics of one or more battery cells based on the functionalized representation at the first time, the one or more measured characteristics at the second time, and the one or more measured characteristics at the third time. The instructions, when executed by the processor, also cause the battery management system to determine the capacity of the one or more battery cells based on the estimated one or more characteristics of the one or more battery cells.

Embodiments of the disclosure are related to a method of managing a battery system, the battery system including at least one battery cell, at least one sensor configured to measure at least one characteristic of the battery cell, and a battery management system including a microprocessor and a memory. The method includes receiving, by the battery management system, a functionalized representation of one or more characteristics of one or more battery cells at a first time. The method also includes receiving, by the battery management system, one or more measured characteristics of one or more battery cells from one or more sensors at a second time, including a characteristic selected from a group consisting of a current measurement of the one or more battery cells, a voltage measurement of the one or more battery cells and a charge measurement of the one or more battery cells. The method also includes receiving, by the battery management system, one or more measured characteristics of the one or more battery cells from the one or more sensors at a third time, including a characteristic selected from the group consisting of a current measurement of the one or more battery cells, a voltage measurement of the one or more battery cells and a charge measurement of the one or more battery cells, wherein the third time is after the second time. The method also includes estimating, by the battery management system, one or more characteristics of one or more battery cells based on the functionalized representation at the first time, the one or more measured characteristics at the second time, and the one or more measured characteristics at the third time. The method also includes determining, by the battery management system, the capacity of the one or more battery cells based on the estimated one or more characteristics of the one or more battery cells.

Embodiments of the disclosure are related to a battery system including, one or more battery cells comprising an anode, a cathode and an electrically insulating separator located between the anode and the cathode, wherein the electrically insulating separator electrically insulates the anode from the cathode. The battery system additionally includes a battery management system comprising a processor and a memory storing instructions. The instructions, when executed by the processor, cause the battery management system to receive a. functionalized representation of one or more characteristics of one or more battery cells at a first time. The battery management system also receives one or more measured characteristics of one or more battery cells from one or more sensors at a second time, including a characteristic selected from a group consisting of a current measurement of the one or more battery cells, a voltage measurement of the one or more battery cells and a charge measurement of the one or more battery cells. The battery management system also estimates at least a portion of a function representing the one or more measured characteristics based on the one or more measured. characteristics of the one or more battery cells. The battery management system also determines one or more significant points of the function representing the one or more measured characteristics at the second time. The battery management system also determines one or more associated points of the function representing one or more characteristics of one or more battery cells at the first time corresponding to the one or more significant points of the function representing the one or more measured characteristics at the second time. The battery management system updates the functionalized representation of the one or more characteristics of the one or more battery cells at the first time based on the one or more measured characteristics at the second time and determines the capacity of the one or more battery cells based on the updated function representing the one or more characteristics of the one of more battery cells.

The details of one or more features, aspects, implementations, and advantages of this disclosure are set forth in the accompanying drawings, the detailed description, and the claims below.

### BRIEF DESCRIPTION OF THE DRAWINGS

FIG. 1 is a block diagram of a battery system including a battery cell and a battery management system with sensing circuitry located external to the battery cell, in accordance with some embodiments.

FIG. 2 is an illustration of the open circuit voltage and charge level of a battery cell.

FIG. 3 is an illustration of the cathode open circuit potential and the anode open circuit potential of a battery cell.

FIG. 4 is an illustration of the updating of the function representing the open circuit potential of the cathode and the open circuit potential of the anode.

FIG. 5 is a flowchart describing an embodiment of a method for determining the capacity of a battery cell.

FIG. 6 is a flowchart describing an embodiment of a method for regulating the operation of a battery cell.

### DETAILED DESCRIPTION

One or more specific embodiments will be described below. Various modifications to the described embodiments will be readily apparent to those skilled in the art, and the general principles defined herein may be applied to other embodiments and applications without departing from the spirit and scope of the described embodiments. Thus, the described embodiments are not limited to the embodiments shown, but are to be accorded the widest scope consistent with the principles and features disclosed herein.

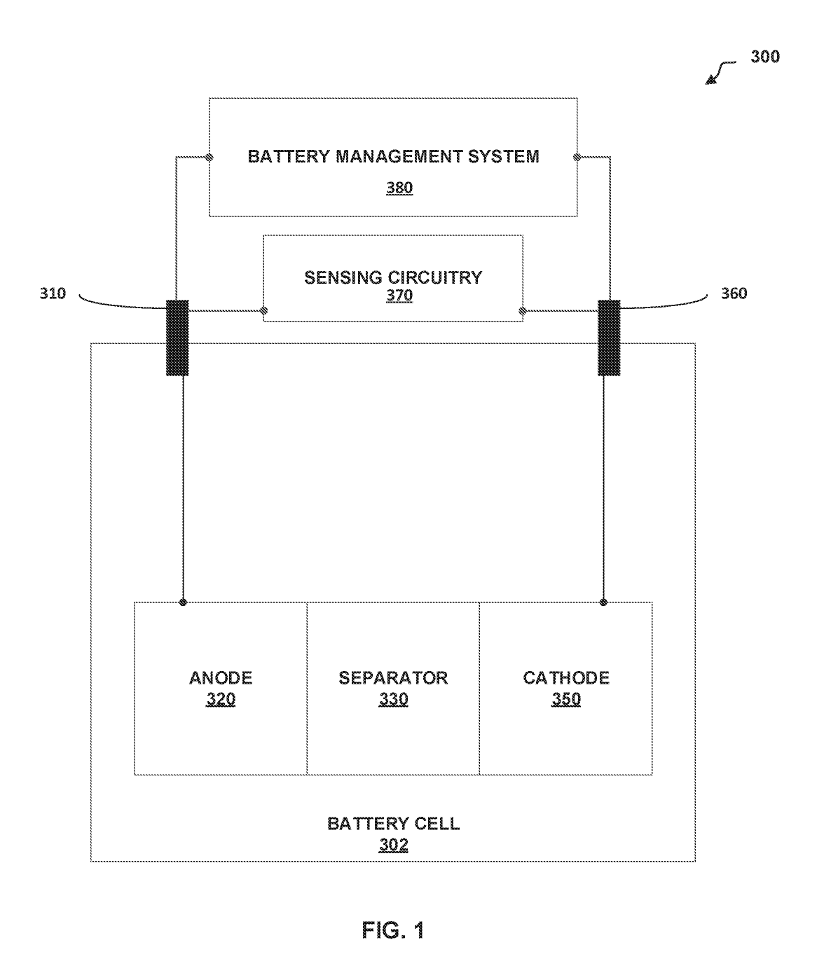

An embodiment of a battery system 300 is shown in FIG. 1. The battery system 300 0 includes an anode tab 310, an anode 320, a separator 330, a cathode 350, a cathode tab 360, a sensing circuitry 370, and a battery management system 380. In some examples, the separator 330 may be an electrically insulating separator. In some embodiments, the electrically insulating separator includes a porous polymeric film. In some embodiments, the thickness of the anode 320 may be about 25 micrometers to about 150 micrometers. In other embodiments, the thickness of the anode 320 may be outside of the previous range. In some embodiments, the thickness of the separator 330 may be about 10 micrometers to about 25 micrometers. In other embodiments, the thickness of the separator 330 may be outside of the previous range. In some embodiments, the thickness of the cathode 350 may be about 10 micrometers to about 150 micrometers. In other embodiments, the thickness of the cathode 350 may outside the previous range.

During the discharge of the battery cell 302, lithium is oxidized at the anode 320 to form a lithium ion. The lithium ion migrates through the separator 330 of the battery cell 302 to the cathode 350. During charging the lithium ions return to the anode 320 and are reduced to lithium. The lithium may be deposited as lithium metal on the anode 320 in the case of a lithium anode 320, or inserted into the host structure in the case of an insertion material anode 320, such as graphite. The process is repeated with subsequent charge and discharge cycles. In the case of the graphitic or other Li-insertion electrode, the lithium cations are combined with electrons and the host material (e.g., graphite), results in an increase in the degree of lithiation, or “state of charge” of the host material. For example, x Li⁺+x e⁻+C₆→LiₓC₆.

The anode 320 may include an oxidizable metal, such as lithium or an insertion material that can insert Li or some other ion (e.g., Na, Mg, or other suitable ion). The cathode 150 may include various materials such as sulfur or sulfur-containing materials (e.g., polyacrylonitrile-sulfur composites (PAN-S composites), lithium sulfide (Li₂S)); vanadium oxides (e.g., vanadium pentoxide (V₂O₅)); metal fluorides (e.g., fluorides of titanium, vanadium, iron, cobalt, bismuth; copper and combinations thereof); lithium-intercalation materials (e.g., lithium nickel manganese cobalt oxide (NMC), lithium-rich NMC, lithium nickel manganese oxide (LiNi_{0.5}Mn_{1.5}O₄)); lithium transition metal oxides (e.g., lithium cobalt oxide (LiCoO₂), lithium manganese oxide (LiMwO₄), lithium nickel cobalt aluminum oxide (NCA), and combinations thereof); lithium phosphates (e.g., lithium iron phosphate (LiFePO₄)); additional materials that react with the working ion; and/or blends of several different materials that insert and/or react with the working ion.

The particles may further be suspended in a porous, electrically conductive matrix that includes polymeric binder and electronically conductive material such as carbon (carbon black, graphite, carbon fiber, etc.). In some examples, the cathode may include an electrically conductive material having a porosity of greater than 80% to allow the formation and deposition/storage of oxidation products such as lithium peroxide (Li₂O₂) or lithium sulfide, (Li₂S) in the cathode volume. The ability to deposit the oxidation product directly determines the maximum power obtainable from the battery cell. Materials which provide the needed porosity include carbon black, graphite, carbon fibers, carbon nanotubes, and other non-carbon materials. The pores of the cathode 350, separator 330, and anode 320 are filled with an ionically conductive electrolyte that includes a salt such as lithium hexafluorophosphate (LiPF₆) that provides the electrolyte with an adequate conductivity which reduces the internal electrical resistance of the battery cell. The electrolyte solution enhances ionic transport within the battery cell 302. Various types of electrolyte solutions are available, including non-aqueous liquid electrolytes, ionic liquids, solid polymers, glass-ceramic electrolytes, and other suitable electrolyte solutions.

The separator 330 may include one or more electrically insulating ionic conductive materials. In some examples, the suitable materials for separator 330 may include porous polymers filled with liquid electrolyte, ceramics, and/or ionically-conducting polymers. In certain examples, the pores of the separator 330 may be filled with an ionically conductive electrolyte that contains a lithium salt (for example, a lithium hexafluorophosphate (LiPF₆)) that provides the electrolyte with an adequate conductivity which reduces the internal electrical resistance of the battery cell.

The battery management system 380 is communicatively connected to the battery cell 302. In one example, the battery management system 380 is electrically connected to the battery cell 302 via electrical links (e.g., wires). In another example, the battery management system 380 may be wirelessly connected to the battery cell 302 via a wireless communication network. The battery management system 380 may include, for example, a microcontroller (the microcontroller having an electronic processor, memory, and input/output components on a single chip or within a single housing). Alternatively, the battery management system 380 may include separately configured components, for example, an electronic processor, memory, and. input/output components. The battery management system 380 may also be implemented using other components or combinations of components including, for example, a digital signal processor (DST), an application specific integrated circuit (ASIC), a field-programmable gate array (FPGA), or other circuitry. Depending on the desired configuration, the processor may include one or more levels of caching, such as a level cache memory, one or more processor cores, and registers. The example processor core may include an arithmetic logic unit (ALU), a floating point unit (FPU), or any combination thereof. The battery management system 380 may also include a user interface, a communication interface, and other computer implemented devices for performing features not defined herein may be incorporated into the system. In some examples, an interface bus for facilitating communication between various interface devices, computing implemented devices, and one or more peripheral interfaces to the microprocessor may be provided.

In the example of FIG. 1, a memory of the battery management system 380 stores computer-readable instructions that, when executed by the electronic processor of the battery management system 380, cause the battery management system 380 and, more particularly the electronic processor, to perform or control the performance of various functions or methods attributed to battery management system 380 herein (e.g., receive measured characteristics, receive estimated characteristics, calculate a state or parameter of the battery system, regulate the operation of the battery system). In an embodiment the battery management system 380 regulates the charging of the battery cell 302 by executing a plurality of stepwise charging modes which allow for rapid charging of the battery while minimizing deleterious effects. The memory may include any transitory, non-transitory, volatile, non-volatile, magnetic, optical, or electrical media, such as a random access memory (RAM), read-only memory (ROM), non-volatile RAM (NVRAM), electrically-erasable programmable ROM (EEPROM), flash memory, or any other digital or analog media. The functions attributed to the battery management system 380 herein may be embodied as software, firmware, hardware or any combination thereof.

In one example, the battery management system 380 may be embedded in a computing device and the sensing circuity 370 is configured to communicate with the battery management system 380 of the computing device external to the battery cell 302. In this example, the sensing circuitry 370 is configured to have wireless and/or wired communication with the battery management system 380. For example, the sensing circuitry 370 and the battery management system 380 of the external device are configured to communicate with each other via a network. In yet another example, the battery management system 380 is remotely located on a server and the sensing circuitry 370 is configured to transmit data of the battery cell 302 to the battery management system 380. In the above examples, the battery management system 380 is configured to receive the data and send the data to the computing device for display as human readable format. The computing device may be a cellular phone, a tablet, a personal digital assistant (PDA), a laptop, a computer, a wearable device, or other suitable computing device. The network may be a cloud computing network, a server, a wireless area network (WAN), a local area network (LAN), an in-vehicle network, or other suitable network.

The battery management system 380 is configured to receive data from the sensing circuitry 370 including current, voltage, temperature, and/or resistance measurements. The battery management system 380 is also configured to determine a condition of the battery cell 302. Based on the determined condition of battery cell 302, the battery management system 380 may alter the operating parameters of the battery cell 302 to maintain the internal states (e.g., the internal states include an anode surface overpotential) of the battery cell 302 within predefined constraints, or constraints that are adapted to the estimated condition of the battery cell 302. The battery management system 380 may also notify a user of the condition of the battery cell 302.

The open-circuit voltage (OCV) of the battery cell 302 is defined in terms of the measured voltage of the battery cell 302. The sensing circuitry 370 (e.g., a voltmeter) with leads attached to the positive terminal 360 and the negative terminal 310 of the battery cell 302 can be used to measure the battery cell voltage. The battery cell voltage is the difference in the potential of the positive terminal 360 and the potential of the negative terminal 310 of the battery cell 302. The battery cell voltage may vary as current is passed through the battery cell 302 via the positive terminal 360 and the negative terminal 310. In some embodiments, the battery cell voltage may be represented as a function of the charge level Q (e.g., ampere hours, coulombs) through the battery cell 302, as represented by the equation:

OCV₁(Q)=f_{cat}(Q)−fₐₙ(Q) (1)

where OCV₁ is a first open circuit voltage function, Q is the charge level, f_{cat} is a first open circuit cathode potential function, and fₐₙ is a first open circuit anode potential function.

The battery cell voltage may also vary when no current is applied to or drawn from the battery cell due to the relaxation of concentration gradients within the battery cell. When the concentration gradients reach zero (e.g., uniform concentration in each phase of the battery cell) and no current is flowing through the battery cell, the battery cell voltage is equal to an equilibrium potential of the battery cell, or “open-circuit potential.” The equilibrium potential is achieved when the battery cell relaxes (i.e., zero current) for an infinite period of time. In practical applications the battery cell does not relax for an infinite period of time. Accordingly, the battery cell achieves a “quasi equilibrium” state where the battery cell voltage changes very slowly with time, the concentration profiles are nearly flat, and negligible current is flowing within the battery cell. The quasi equilibrium state occurs during long “rest periods” of zero applied current and removal of load from the battery cell. In the following discussion of OCP measurements, it is understood that a battery management system 380 measures the battery cell voltage and monitors the change of the battery cell voltage with time. It is also understood that the battery management system 380 extracts an OCP only when the battery cell is sufficiently relaxed (e.g., dV/dt<e, where e is a small number, usually less than 3 millivolts per hour (mV/hour)). Additionally or alternatively, the battery management system 380 may use a mathematical model for the battery cell and parameter estimation algorithms to determine the value of the OCP even while the battery cell is under load. Additionally or alternatively, the battery management system 380 may extrapolate a value of the OCP from the measured battery cell voltage versus time data.

The relationship between active electrode material capacities, cyclable lithium, and the open-circuit potential (OCP), of a complete battery cell can be represented by mathematical equations. In particular, for a blended electrode, i.e., one that has more than one active electrode material, the overall state of charge (SOC) of the electrode is given by the weighted sum of the individual materials state of charge as follows:

$$y = {\sum }_{i} {f}_{i} {y}_{i} \qquad ( 2 )$$

where, yᵢ is the state of charge of each individual material, y is the composite state of charge, fᵢ is the fraction of Li sites present in each material i and where

$$1 = {\sum }_{i} {f}_{i} \qquad ( 3 )$$

The equilibrium voltage of the mixed electrode is equal to the open-circuit potentials of each component at its respective state of charge. That is, for every material i,

U(y)=Uᵢ(yᵢ) (4)

All Uᵢ values, and therefore U, are monotonic with yᵢ and y, respectively. Hence, for a given U=Uᵢ, there are unique values of y and yᵢ. Starting with an arbitrary value of U, we obtain through U=Uᵢ all values of yᵢ. From a set of fᵢ, we further obtain the value of y via equation (2).

The battery cell voltage may also vary when no current is applied to or drawn from the battery cell due to the relaxation of concentration gradients within the battery cell. When the concentration gradients reach zero (e.g., uniform concentration in each phase of the battery cell) and no current is flowing through the battery cell, the battery cell voltage is equal to an equilibrium potential of the battery cell, or “open-circuit potential.”

The capacity of a blended electrode to store charge is given by the weighted sum of the individual materials as follows:

C_{Δ,blend}=ΣᵢβᵢC_{Δ,i}(U) (5)

where C_{Δ,blend} is the capacity of the electrode, βᵢ is a scaling factor of the i^{th} material, and C_{Δ,i} (U) is the capacity of the i^{th} material.

The charge level Q of the blended electrode over a potential range is given by the integral over the potential range of the capacity as represented by the equation:

Q_{blend}(U)=∫_{U}_{ₘᵢₙ}^{U}^{ₘₐₓ}C_{Δ,blend}dU (6)

The potential of the blended electrode as a function of charge level Q is inversely proportional to the charge level Q as a function of potential which is represented by the relationship:

U_{blend}(Q)=f⁻¹(Q_{blend}(U)) (7)

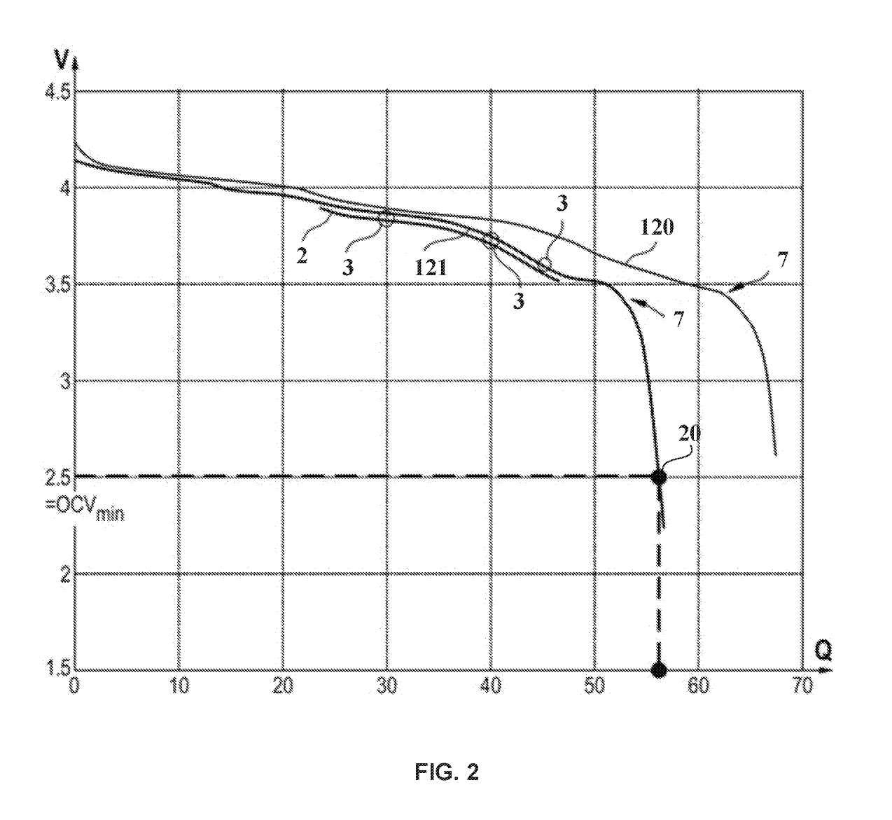

FIG. 2 illustrates the open circuit voltage versus the charge level Q for the battery cell 302. The charge level Q describes a charge quantity, (e.g., ampere hours, coulombs), delivered by the battery starting from a fully charged state. In the example of FIG. 2, the battery management system 380 may contain a first open circuit voltage function 120 representing an open circuit voltage characteristic of the battery cell 302 at a first state of ageing (e.g., beginning of life). A second open circuit voltage function 121 represents a second open circuit voltage characteristic at a second state of ageing of the battery cell 302. In some embodiments, the second state of ageing is after the first state of ageing. In some embodiments, the open circuit voltage function 121 represents the current open circuit voltage characteristics of the battery cell 302.

In the example of FIG. 2, an acquired portion 2 of discrete data points may be received by the battery management system 380 from the sensing circuitry 370. In some embodiments, the acquired portion 2 may correspond to points of the second open circuit voltage function 121. In some embodiments, the battery management system 380 may interpolate the acquired portion 2 of the second open circuit voltage function 121 to yield a continuous function that may approximate a section of the second open circuit voltage function 121. In some embodiments, the interpolated acquired function 2 may be differentiable.

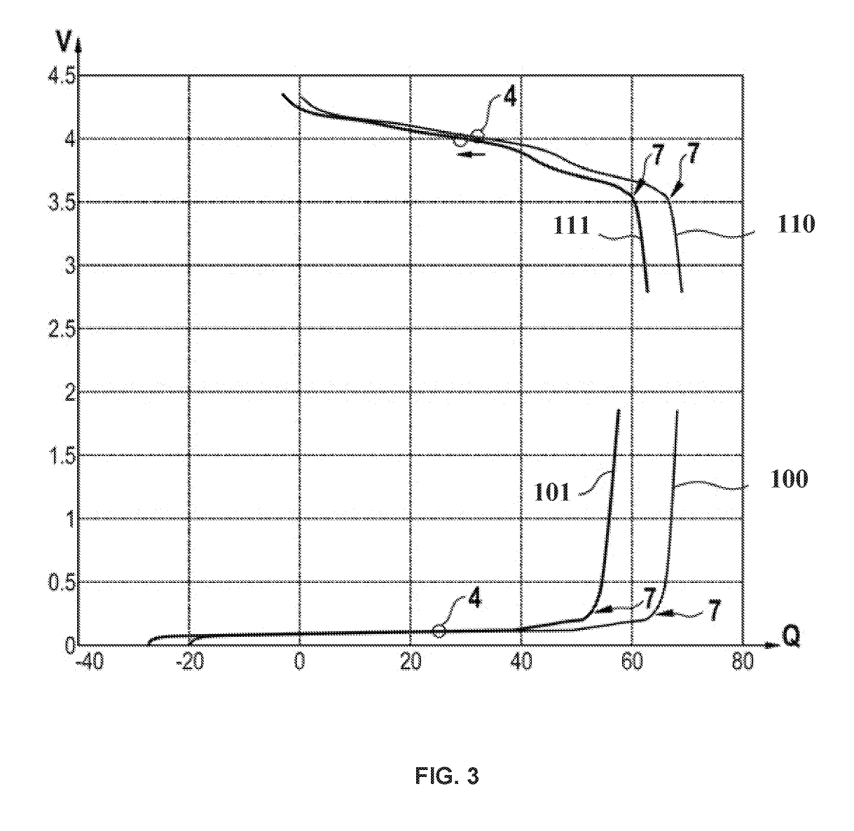

FIG. 3 illustrates the open circuit potential of the cathode versus the delivered charge Q and the open circuit potential of the anode versus the charge level Q for a battery cell 302. The battery cells 302 represented in each of the examples that are illustrated in FIGS. 2 and 3 are the same. In the example of FIG. 3, the battery management system 380 may contain a first open circuit cathode potential function 110 representing the first open circuit cathode potential at a first state of ageing (e.g., beginning of life) of the battery cell 302. In some embodiments, the first open circuit cathode potential function 110 may be described as a function of the charge level Q for the battery cell 302 (e.g., f_{cat} (Q)). A second open circuit cathode potential function 111 represents the second open circuit cathode potential at a second state of ageing of the battery cell 302. In some embodiments, the second state of ageing is after the first state of ageing. In some embodiments, the second open circuit cathode potential function 111 may represent the current open circuit cathode potential characteristics of the battery cell 302.

In the example of FIG. 3, the battery management system 380 may contain a first open circuit anode potential function 100 representing a first open circuit anode potential 100 at a first state of ageing (e.g., beginning of life) of the battery cell 302. A second open circuit anode potential function 101 represents a second open circuit anode potential function at a second state of ageing of the battery cell 302. In some embodiments, the second state of ageing is after the first state of ageing. In some embodiments, the second open circuit anode potential function 101 may represent the current open circuit anode potential characteristics of the battery cell 302.

In some embodiments, the battery management system 380 may determine the first open-circuit voltage function 120 from the first open circuit anode potential function 100 and the first open circuit cathode potential function 110. For example, the first open-circuit voltage function 120 may be determined from the first open circuit anode potential function 100 and the first open circuit cathode potential function 110 when the battery cell 302 is initially constructed (i.e., the beginning of life of the battery).

As the battery cell 302 ages the open circuit cathode potential function 150 and the open circuit anode potential function 120 may change. In some embodiments, the battery management system 380 may use measured values of the open circuit voltage (e.g., acquired portion 2) to approximately determine a portion of the second open circuit voltage function 121. In some embodiments, the battery management system 380 approximately determines the second (e.g., current) open circuit cathode potential function 111 and approximately determines the second (e.g., current) open circuit anode potential function 101 based on the approximately determined portion of the second open circuit voltage function 121. In some embodiments, the battery management system 380 determines the second (e.g., current) open circuit cathode potential function 111 and the second (e.g., current) open circuit anode potential function 100 based on shifting and/or scaling the functions of the first open circuit cathode potential function 110 and the first open circuit anode potential function 100. Examples of the scaled and/or shifted first cathode potential, first anode potential and resulting second open circuit voltage functions are represented by the equations:

f_{cat} (α_{cat} Q+β_{cat}) (8)

fₐₙ(αₐₙ Q+βₐₙ) (9)

OCV₂(Q)=f_{cat}(α_{cat} Q+β_{cat})−fₐₙ(αₐₙ Q+βₐₙ) (10)

where α_{cat} is a cathode scaling factor, β_{cat} is a cathode shifting factor, αₐₙ is an anode scaling factor, βₐₙ is an anode shifting factor, Q is the charge level Q and OCV₂ is the second open circuit voltage function. The cathode scaling factor and the anode scaling factor may be the same or different. The cathode shifting factor and the anode shifting factor may be the same or different.

In some embodiments, the battery management system 380 uses the measured open circuit voltage (e.g., acquired portion 2) to approximately determine at least a portion of the second (e.g., current) open circuit voltage function 121. In some embodiments, the battery management system 380 differentiates the acquired function 2 to determine a first derivative and/or a second derivative of the acquired function 2. In some embodiments, the battery management system 380 determines one or more significant points 3 (e.g., local minima, local maxima, point of inflection and combinations thereof) of the acquired function 2 based on the first and/or second derivative of the acquired function 2. Alternatively, the battery management system 380 determines one or more significant points 3 based on patterns (e.g., curve characteristics) of the open circuit voltage function 7. In some embodiments, the battery management system 380 determines one or more associated points 4 on the first open circuit cathode potential function 110 and one or more associated points 4 or curve characteristics on the first open circuit anode potential function 100 which correspond to one or more of the one or more significant points 3 or curve characteristics 7 respectively on the second open circuit voltage function 121.

In some embodiments, the battery management system 380 shifts and/or scales the first open circuit cathode potential function 110 and/or the first open circuit anode potential function 100 such that the one or more associated points 4 corresponding to the significant points 3 are aligned with the significant point 3 and/or the Q value associated with the one or more significant points 3. In some embodiments, the battery management system 380 determines values for the α_{cat} cathode scaling factor α_{cat}, cathode shifting factor β_{cat}, anode scaling factor αₐₙ, and anode shifting factor βₐₙ based on the amounts of shifting and scaling needed to align the one or more associated points 4 of the first open circuit cathode potential function 110 and/or the first open circuit anode potential function 100 with the corresponding one or more significant points 3 and/or the Q value associated with the one or more significant points 3.

In some embodiments, the battery management system 380 determines (e.g., estimates) the actual (e.g., current) second open circuit voltage function 121 based on the shifted and/or scaled first open circuit cathode potential function 110 and the shifted and/or scaled first open circuit anode potential function 100. The relationship between the second open circuit voltage function 121 and the shifted and/or scaled first open circuit cathode potential function and the shifted and/or scaled first open circuit anode potential function may be represented by the equation:

OCV_{act} (Q)=f_{cat} (α_{cat} Q+β_{cat})−fₐₙ (αₐₙ Q+βₐₙ) (11)

where α_{cat} is a cathode scaling factor, β_{cat} is a cathode shifting factor, aₐₙ is an anode scaling factor, βₐₙ is an anode shifting factor, Q is the charge level Q and OCV_{act} is the estimated actual second (e.g., current) open circuit voltage.

In certain embodiments, the underlying functions f_{cat} (Q) and fₐₙ (Q) describe the cathode potential 110 at the time of the production of the battery and the anode potential 100 at the time of production of the battery respectively. Thus, the calculated actual (e.g., current) second open-circuit voltage function is an estimated current second open-circuit voltage function based on the characteristics of the battery at the time of production.

In some embodiments, the battery management system 380 determines a capacity of the battery cell 302 based on the estimated actual (e.g., current) second open circuit voltage curve. The capacity of the battery cell 302 is calculated based on the estimated current open circuit voltage curve and a predefined minimum open circuit battery cell voltage 20. The charge level Q associated with the predefined minimum open circuit battery cell voltage 20 describes the maximum capacity of the battery.

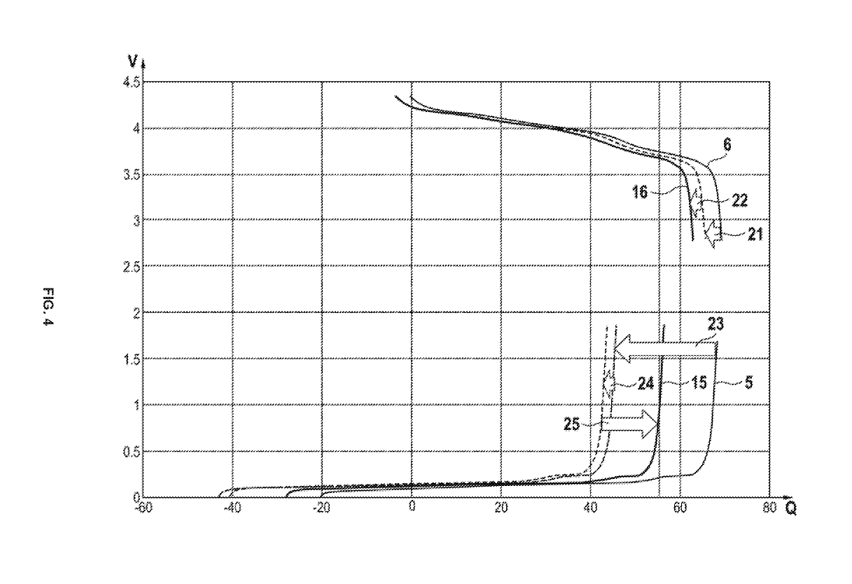

FIG. 4 illustrates an example of the shifting and scaling of the first cathode potential function 6 and the first anode potential function 5. In the example of FIG. 4, the battery management system 380 first scales the first cathode potential function 6, based on the significant points 3 and associated points 4, as represented by a first arrow 21. The battery management system 380 then shifts the first cathode potential function 6, based on the significant points 3 and associated points 4, as described above, as represented by a second arrow 22. In the example of FIG. 4, the battery management system 380 shifts the cathode potential function 6 in such a manner that the second (e.g., current) potential of the cathode 150 is described by the resulting second cathode potential function 16 when the battery cell 302 is fully charged. The factor α_{cat} is therefore determined, at least provisionally, by the scaling of the characteristic curve of the first cathode potential function 6. The factor β_{cat} is therefore determined, at least provisionally, by the shifting of the characteristic curve of the first cathode potential function 6. The second cathode potential function 16 may be represented by the equation:

OCP_{cat}=f_{cat} (Q·γ·δ) (12)

where OCP_{cat} is the current open circuit cathode potential, Q is the charge level, γ is the determined value of the scaling factor α_{cat}, and δ is the determined value of the shifting factor β_{cat}.

In the example of FIG. 4, the characteristic curve of the first anode potential function 5 is scaled and shifted by the battery management system 380. The shifting and scaling of the first anode potential function 5, resulting in the second (e.g., current) anode potential function 15 as represented by the equation:

OCPₐₙ=fₐₙ ([Q−p_{BOL}]·γ+p_{ACT}) (13)

where OCPₐₙ is the current open circuit anode potential, Q is the charge level, p_{BOL} is the charge level at which the significant point 3 occurs when the battery cell 302 is at the start of its life cycle (i.e., beginning of life), γ is the determined value of the scaling factor aₐₙ, and p_{ACT} is the charge level at which the significant point 3 occurs in the actual (e.g., current) open-circuit voltage function.

In the example of FIG. 4 the battery management system 380 may perform a weighted shift of the open circuit anode potential function, resulting from the term [Q−p_{BOL}], as represented by a third arrow 23. In some embodiments, the battery management system 380 may scale the open circuit anode potential function by a scaling by the scaling factor γ as represented by a fourth arrow 24. In some embodiments, the battery management system 380 may shift the open circuit anode potential function by the value p_{ACT} as represented by a fifth arrow 25.

In the example of FIG. 4, the battery management system 380 shifts the characteristic functions in a predefined manner. Only one scaling factor, γ, on which both the characteristic curve of the first anode potential function 5 and the characteristic curve of the first cathode potential function 6 depend, is varied, in order to minimize the variation between the acquired portion 2 of the actual current open-circuit voltage characteristic and the associated portion of the temporary open-circuit voltage characteristic. The scaling factor, γ, may be determined from the location of the associated point 4 on one or both of the first cathode potential function 6 and/or the first anode potential function 5.

In an alternate embodiment, the charge level of the cathode and the charge level of the anode may differ. The battery management system 380, determines the current capacity of the battery based on the charge levels of the anode Q+ and of the cathode Q− independently. The technique corresponds to the embodiments described above, but with the anode potential function 5 and the cathode potential function 6 being considered independently. In some embodiments, the cathode potential function 6 and the anode potential function 5 may be shifted and/or scaled by the same or different shifting and/or scaling factors.

The open circuit potential of the cathode 150 and the open circuit potential of the anode 320 are related to the amount of active materials present. The state of charge of the cathode (SOC+) reflects the ratio of the charge level of the cathode 350 relative to the capacity of the cathode 350 to store charge (Q+/C+) within the active cathode materials. Similarly, state of charge of the anode (SOC−) reflects the ratio of the charge level of the anode 320 relative to the capacity of the anode 320 to store charge, (Q−/C−) within the active anode materials. As described above, the open circuit voltage (OM of the battery cell 302 is related to the electrode potentials as represented by the equation:

OCV_{cell}=OCP+(Q+/C+)−OCP−(Q−/C−) (14)

where OCV_{cell} is the open circuit voltage of the battery cell 302, OCP+ is the open circuit potential of the cathode 350, Q+ is the charge level of the cathode, C+ is the capacity of the cathode, OCP− is the open circuit potential of the anode, and Q− is the charge level of the anode and C− is the capacity of the anode.

As the battery cell 302 ages the capacity of the anode 320 and the cathode 350 to store charge may decrease. The relationship between the capacity of the anode 320 at the beginning of life of the anode 320 and the capacity of the anode 320 during the operational life of the anode 320 may be represented by the state of health (SOH−) of the anode 320. The relationship between the capacity of the cathode 350 at the beginning of life of the cathode 350 and the capacity of the cathode 350 during the operational life of the cathode 350 may be represented by the state of health (SOH+) of the cathode 350.

The battery management system 380 may determine the maximum capacity of the battery cell 302 at the current state of health from the open circuit voltage of the battery cell 302, the charge level of the anode 320 (Q−) and the charge level of the cathode 350 (Q+). In the example of FIG. 4, the current maximum charge levels of the anode 320 and cathode 350 are determined based on the shifting and/or scaling of the first open circuit cathode potential function 6 and the first open circuit anode potential function 5. The maximum still achievable charge levels are determined on the basis of a discharge state of the battery. This discharge state is determined on the basis of the significant point 3. In some embodiments, the position of the significant point 3 in the actual open-circuit voltage characteristic 121 is compared with its position in an open-circuit voltage characteristic at the beginning of its life 120 (BOL).

In some embodiments, the battery management system 380 may estimate the current open circuit voltage function 121 based on an associated point 4 of the anode potential function 5. In some embodiments, the battery management system 380 may estimate the current open circuit voltage function 121 based on an associated point 4 of the cathode potential function 6. In certain embodiments, the battery management system 380 may estimate the current open circuit voltage function 121 based on an associated point 4 of both the anode potential function 5 and the cathode potential function 6. According to the invention, however, it is sufficient if only one associated point 4 is determined, i.e. either in the characteristic curve of the anode potential 5 or in the characteristic curve of the cathode potential 6 of the battery, and one or both of the characteristic curves is/are shifted on the basis of the position of the significant point 3 in respect of the one associated point 4. In some embodiments, the magnitude of the shifting and/or scaling of the anode potential function is similar to the magnitude of the shifting and/or scaling of the cathode potential function. In some embodiments, the shifting and/or scaling of the anode potential function and the shifting and/or scaling of the cathode potential function by a common shifting and/or scaling factor based on one associated point may result in reduce computational costs.

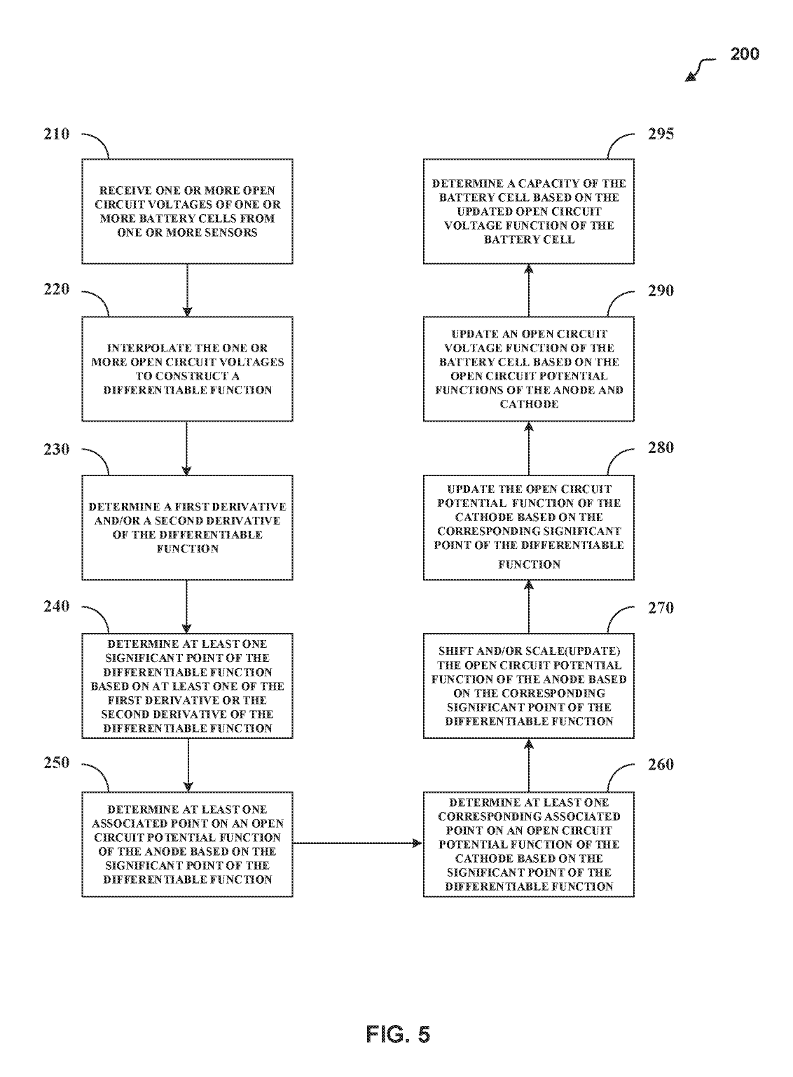

FIG. 5 is a flowchart 200 of a method of determining the capacity of a battery cell 302. In the example of FIG. 5, at block 210, the battery management system 380 receives data from one or more sensors of the sensing circuitry 370 which measure one or more characteristics (e.g., open circuit voltage) of one or more battery cells 302. At block 220, the battery management system 380 interpolates the data received from the sensing circuitry 370 to construct an acquired function based on the received data 2. At block 230, the battery management system 380 determines a first derivative and/or a second derivative of the acquired function 2. At block 240, the battery management system 380 deter mines one or more significant points 3 (e.g., local minima, local maxima, point of inflection) based on the first derivative and/or the second derivative of the acquired function 2. In another embodiment, the battery management system 380 determines one or more significant points 3 of the acquired function 2 based on other characteristics of the acquired function 2. At block 250, the battery management system 380, determines one or more associated points 4 on a first open circuit potential function of the anode 100. In some embodiments, the one or more associated points 4 of the first open circuit potential function of the anode 100 may correspond to the one or more significant points 3 of the acquired function 2. At block 260, the battery management system 380 determines one or more associated points 4 on an open circuit potential function of the cathode 110. In some embodiments, the one or more significant points of the open circuit potential function of the cathode 110 may correspond to the one or more significant points 3 of the acquired function 2. At block 270, the battery management system 380, updates (e.g., shifts and/or scales) the first open circuit potential function of the anode 100 based on the one or more significant points 3 of the acquired function 2. At block 280, the battery management system 380, updates (e.g., shifts and/or scales) the first open circuit potential function of the cathode 110 based on the one or more significant points 3 of the acquired function 2 resulting in the second open circuit cathode potential function 111. In some embodiments, the update to the open circuit potential function of the anode 100 may be the same as the update to the first open circuit potential function of the cathode 110. In some embodiments, the update to the open circuit potential function of the anode 100 may be different from the update to the open circuit potential function of the cathode 110. At block 290, the battery management system 380, updates an open circuit voltage function 120 of the battery cell 302. At block 295, the battery management system 380, determines the capacity of the battery cell 302 based on the open circuit voltage function of the battery cell 302.

In some embodiments, the battery management system 380 may receive measurement data including voltage, charge value and time. In some embodiments, the battery management system 380 receives data (e.g., voltage and time) continuously during the operation of the battery cell 302. In some embodiments, the open circuit voltage function, described above, may vary slowly due to the aging of the battery cell 302. In some embodiments, the open circuit voltage function may be updated periodically (e.g., 1 charge/discharge cycle, 5 charge/discharge cycles, 10 charge/discharge cycles).

In some embodiments, the battery management system 380 may calculate the capacity of the battery cell 302 without updating the open circuit voltage function. The battery management system 302 may use the measured data (e.g., voltage, charge level, current and time) to determine the capacity based on two or more data points collected at any two times corresponding to a relaxed value during the discharge of the battery cell 302. The battery management system 302 may apply statistical algorithms to the collected data (e.g., a least squares algorithm) which may reduce the differences between the measured values and predicted values based on the open circuit voltage function.

In some embodiments, the minimization of the difference between the measured values and predicted values may be given by the relationship:

Min[(ΔQ_{12,mdl}−ΔQ₁₂)²+( . . . )+(ΔQ_{1n,mdl}−ΔQ₍₁ₙ₎)²] (15)

where ΔQ_{12,mdl} is the predicted difference in the charge level between data points 1 and 2 based on the open circuit voltage function, ΔQ₁₂ is the measured difference in the charge level between data points 1 and 2, ΔQ_{1n,mdl} is the predicted difference in the charge level between data points 1 and n based on the open circuit voltage function, ΔQ₁ₙ is the measured difference in the charge level between data points 1 and n.

In this exemplary embodiment of the battery management system 302, the system 302 calculates the differences of charge level ΔQ and apply statistical algorithms to the collected data such as a least squares algorithm and eliminates the reference voltage OCVₘₐₓ. In doing so, the system 302 can perform faster at any two arbitrary voltage points without the reference voltage measurement (e.g. uses OCVₘₐₓ which is the maximum open circuit voltage as the reference point and for calibration of the charge indicator by returning back to OCVₘₐₓ for reference voltage measurement is eliminated). A published application WO2014/130519 is incorporated herein by reference.

In some embodiments, the battery management system 380 may determine a state of health (e.g., capacity, internal short) of the battery cell 302 based on the open circuit voltage function and data fit as described above. In some embodiments, the battery management system 380 may notify a user of the condition of the battery cell 302 (e.g., presence of an internal short or the amount of remaining capacity).

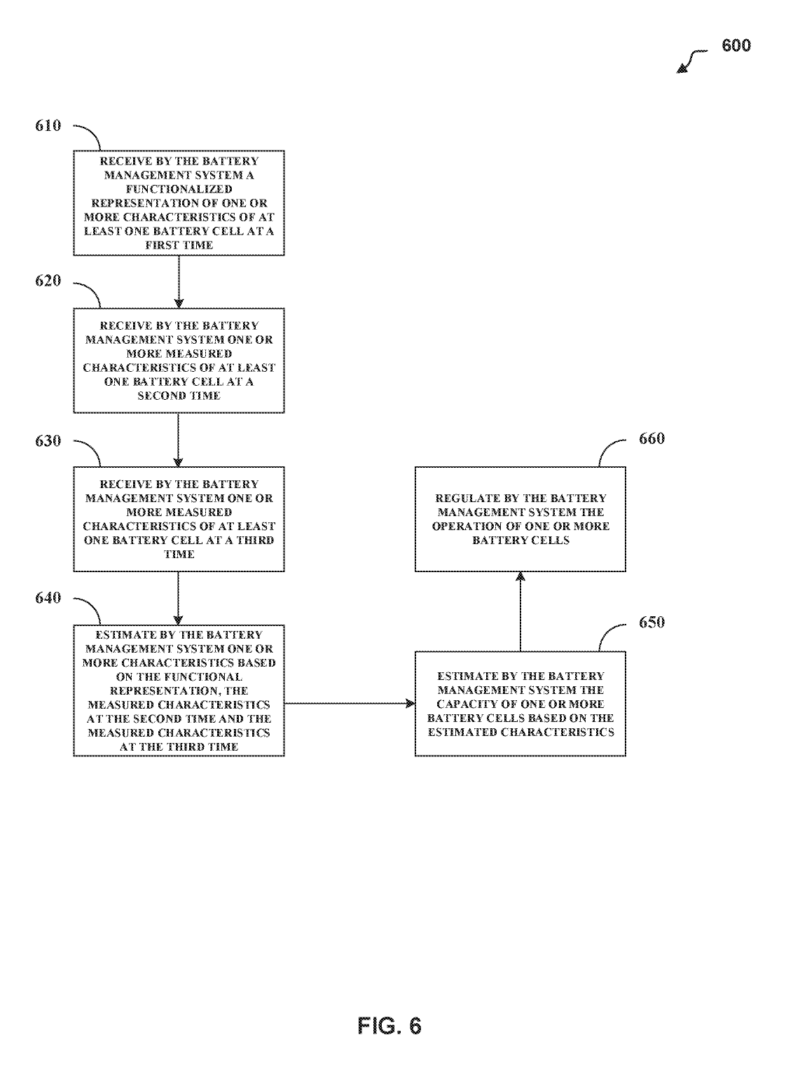

FIG. 6 is a flowchart 600 of a method of determining the capacity of a battery cell 302. In the example of FIG. 6, at block 610, the battery management system 380 receives a functionalized representation of one of more battery cells 302 at a first time. At block 620 the battery management system 380 receives data from one or more sensors of the sensing circuitry 370 which measure one or more characteristics (e.g., open circuit voltage) of one or more battery cells 302 at a second time. At block 630, the battery management system 380 receives data from one or more sensors of the sensing circuitry 370 which measure one or more characteristics (e.g., open circuit voltage) of one or more battery cells 302 at a third time. At block 640, the battery management system 380 estimates one or more characteristics based on the functional representation, the measured characteristics at the second time and the measured characteristics at the third time. At block 650, the battery management system estimates the capacity of one or more battery cells based on the estimated characteristics. At block 660, the battery management system 380 regulates the operation of one or more battery cells 302 based on the estimated capacity of the battery cell 302.

While the invention has been described with reference to various embodiments, it will be understood that these embodiments are illustrative and that the scope of the disclosure is not limited to them. Many variations, modifications, additions, and improvements are possible. More generally, embodiments in accordance with the invention have been described in the context or particular embodiments. Functionality may be separated or combined in blocks differently in various embodiments of the disclosure or described with different terminology. These and other variations, modifications, additions, and improvements may fall within the scope of the disclosure as defined in the claims that follow.

What is claimed is:

1. A battery system comprising,
one or more battery cells comprising an anode, a cathode and an electrically insulating separator located between the anode and the cathode, wherein the electrically insulating separator electrically insulates the anode from the cathode; and
a battery management system comprising a processor and a memory storing instructions that, when executed by the processor, cause the battery management system to:
receive a functionalized representation of one or more characteristics of one or more battery cells at a first time;
receive one or more measured characteristics of one or more battery cells from one or more sensors at a second time, including a characteristic selected from the group consisting of a current measurement of the one or more battery cells, a voltage measurement of the one or more battery cells and a charge measurement of the one or more battery cells;
receive one or more measured characteristics of the one or more battery cells from the one or more sensors at a third time, including a characteristic selected from the group consisting of a current measurement of the one or more battery cells, a voltage measurement of the one or more battery cells and a charge measurement of the one or more battery cells, wherein the third time is after the second time;
estimate one or more characteristics of one or more battery cells based on the functionalized representation at the first time, the one or more measured characteristics at the second time, and the one or more measured characteristics at the third time;
determine the capacity of the one or more battery cells based on the estimated one or more characteristics of the one or more battery cells.

2. The battery system of claim 1, wherein the anode comprises a plurality of active anode materials:

3. The battery system of claim 1, wherein the cathode comprises a plurality of active cathode materials.

4. The battery system of claim 1, further comprising regulate one or more of the charging of the battery cell or discharging of the battery cell based on the capacity of the battery cell.

5. The battery system of claim 4, wherein the instructions, when executed by the processor, regulates the charging of the battery cell.

6. The battery system of claim 1, wherein the instructions, when executed by the processor, cause the battery management system to estimate the capacity of the one or battery cells at the third time by applying a least squares algorithm.

7. The battery system of claim 6, wherein the functionalized representation comprises a functional representation of the open circuit voltage.

8. A method of managing a battery system, the battery system including at least one battery cell, at least one sensor configured to measure at least one characteristic of the battery cell, and a battery management system including a microprocessor and a memory, the method comprising:
receiving, by the battery management system, a functionalized representation of one or more characteristics of one or more battery cells at a first time;
receiving, by the battery management system, one or more measured characteristics of one or more battery cells from one or more sensors at a second time, including a characteristic selected from a group consisting of a current measurement of the one or more battery cells, a voltage measurement of the one or more battery cells and a charge measurement of the one or more battery cells;
receiving, by the battery management system, one or more measured characteristics of the one or more battery cells from the one or more sensors at a third time, including a characteristic selected from the group consisting of a current measurement of the one or more battery cells, a voltage measurement of the one or more battery cells and a charge measurement of the one or more battery cells, wherein the third time is after the second time;
estimating, by the battery management system, one or more characteristics of one or more battery cells based on the functionalized representation at the first time, the one or more measured characteristics at the second time, and the one or more measured characteristics at the third time;
determining, by the battery management system, the capacity of the one or more battery cells based on the estimated one or more characteristics of the one or more battery cells.

9. The battery system of claim 8, wherein the anode comprises a plurality of active anode materials.

10. The battery system of claim 8, wherein the cathode comprises a plurality of active cathode materials.

11. The battery system of claim 8, further comprising regulate one or more of the charging of the battery cell or the discharging of the battery cell based on the capacity of the battery cell.

12. The battery system of claim 11, wherein the instructions, when executed by the processor, regulates the charging of the battery cell.

13. The battery system of claim 8, wherein the instructions, when executed by the processor, cause the battery management system to estimate the capacity of the one or battery cells at the third time by applying a least squares algorithm.

14. The battery system of claim 8, wherein the functionalized representation comprises a functional representation of the open circuit voltage.

15. A battery system comprising,
one or more battery cells comprising an anode, a cathode and an electrically insulating separator located between the anode and the cathode, wherein the electrically insulating separator electrically insulates the anode from the cathode; and
a battery management system comprising a processor and a memory storing instructions that, when executed by the processor, cause the battery management system to:
receive a functionalized representation of one or more characteristics of one or more battery cells at a first time;
receive one or more measured characteristics of one or more battery cells from one or more sensors at a second time, including a characteristic selected from a group consisting of a current measurement of the one or more battery cells, a voltage measurement of the one or more battery cells and a charge measurement of the one or more battery cells;
estimate at least a portion of a function representing the one or more measured characteristics based on the one or more measured characteristics of the one or more battery cells;
determine one or more significant points of the function representing the one or more measured characteristics at the second time;
determine one or more associated points of the function representing one or more characteristics of one or more battery cells at the first time corresponding to the one or more significant points of the function representing the one or more measured characteristics at the second time;
update the functionalized representation of the one or more characteristics of the one or more battery cells at the first time based on the one or more measured characteristics at the second time;
determine the capacity of the one or more battery cells based on the updated function representing the one or more characteristics of the one of more battery cells.

16. The battery system of claim 1, wherein the anode comprises a plurality of active anode materials.

17. The battery system of claim 1, wherein the cathode comprises a plurality of active cathode materials.
